(19) United States
(12) Patent Application Publication
(10) Pub. No.: US 2004/0118519 A1
(43) Pub. Date: Jun. 24, 2004

(54) Blocker plate bypass design to improve clean rate at the edge of the chamber

(75) Inventors: Soovo Sen, Sunnyvale, CA (US); Maosheng Zhao, Santa Clara, CA (US); Inna Shmurun, Foster City, CA (US); Ju-Hyung Lee, San Jose, CA (US); Shankar Venkataraman, Santa Clara, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/327,209

(22) Filed: Dec. 20, 2002

(51) Int. Cl. H01L 21/306

(52) U.S. Cl. 156/345.33

(57) ABSTRACT

A method and apparatus for distributing gases into a processing chamber. In one embodiment, the apparatus includes a gas distribution plate defining a plurality of holes disposed therethrough, a blocker plate defining a plurality of holes disposed therethrough, a first gas pathway configured to deliver a first gas through the blocker plate and the gas distribution plate, and a second gas pathway configured to deliver a second gas around the blocker plate and through the gas distribution plate.

### BACKGROUND OF THE INVENTION

1. Field of the Invention

Embodiments of the present invention generally relate to semiconductor substrate processing systems, and more specifically, a method and apparatus for delivering gases into the processing chamber.

2. Description of the Related Art

In the fabrication of integrated circuits and semiconductor devices, materials, such as oxides, are typically deposited on a substrate in a process chamber, such as a chemical vapor deposition (CVD) chamber. The deposition processes typically result in deposition of some of the materials on the walls and components of the deposition chamber, such as the gas distribution plate or faceplate. Since the materials are distributed through the gas distribution plate during processing, a layer of deposition is often formed on the gas distribution plate, which may clog the holes of the plate or flake off in particles that rain down on the substrate, thereby affecting the uniformity of deposition on the substrate and contaminating the substrate. Consequently, it is necessary to clean the interior of the deposition chamber on a regular basis.

Several methods of cleaning the deposition chamber, including the gas distribution plate, have been developed. For example, a remote plasma cleaning procedure may be employed in which an etchant plasma is generated remote from the deposition chamber by a high density plasma source, such as a microwave plasma system, toroidal plasma generator or similar device. Dissociated species from the etchant plasma are then transported to the deposition chamber where they can react with and etch away the undesired deposition build up. It is also common to remove the unwanted deposition material that builds up on the interior of chamber walls with an in situ chamber clean operation. Common in situ chamber cleaning techniques include the use of an etchant gas, such as fluorine, to remove the deposited material from the chamber walls and other areas. The etchant gas is introduced into the chamber and plasma is formed so that the etchant gas reacts with and removes the deposited material from the chamber walls.

Since the temperature near or around a perimeter of the gas distribution plate is generally cooler than the temperature at a center of the gas distribution plate after a deposition process, the clean rate near or around the perimeter is generally lower than the clean rate at the center. This lower clean rate near or around the perimeter of the gas distribution plate in turn increases the amount of time it takes to clean the chamber. The longer it takes to clean the chamber, the lower the number of substrates that can be processed in a given time (i.e., throughput) and the more gas that is consumed to clean the chamber.

Therefore, a need exists for an improved method and apparatus for delivering gases, e.g., cleaning gases, into the chamber.

### SUMMARY OF THE INVENTION

Embodiments of the present invention are generally directed to an apparatus for distributing gases into a processing chamber. In one embodiment, the apparatus includes a gas distribution plate defining a plurality of holes disposed therethrough, a blocker plate defining a plurality of holes disposed therethrough, a first gas pathway configured to deliver a first gas through the blocker plate and the gas distribution plate, and a second gas pathway configured to deliver a second gas around the blocker plate and through the gas distribution plate.

Embodiments of the present invention are also directed to a method for processing a substrate, which includes delivering one or more processing gases into a chemical vapor deposition chamber through a first gas pathway, reacting the processing gases to deposit a material on a substrate surface, removing the substrate from the chamber, and delivering one or more cleaning gases into the chamber through a second gas pathway. The first gas pathway is separate from the second gas pathway. The method further includes reacting the cleaning gases with deposits within the chamber until substantially all the deposits are consumed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic view of a CVD system, which incorporates various embodiments of the present invention.

FIG. 2 illustrates a perspective view of a gas distribution assembly for the CVD system, which incorporates various embodiments of the present invention.

FIG. 3 illustrates a top plan view of the gas distribution assembly, which incorporates various embodiments of the present invention.

FIG. 4 illustrates a partial cross section of the gas distribution assembly of FIG. 3 along a section line 4-4.

### DETAILED DESCRIPTION OF THE PREFERRED EMBODIMENT

A detailed description will now be provided. Various terms as used herein are defined below. To the extent a term used in a claim is not defined below, it should be given the broadest definition persons in the pertinent art have given that term, as reflected in printed publications and issued patents. Embodiments of the present invention are generally directed to an apparatus and method for distributing gases into a processing chamber, such as a chemical vapor deposition (CVD) apparatus.

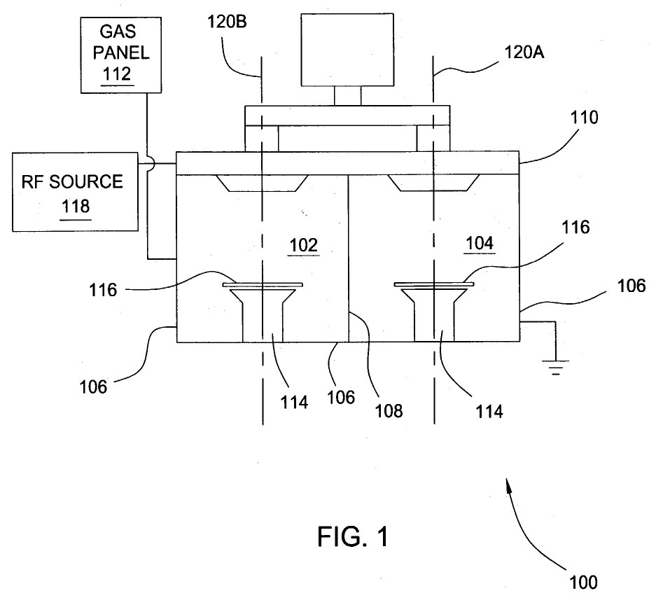

FIG. 1 illustrates an exemplary CVD apparatus 100, which incorporates various embodiments of the present invention. The CVD apparatus 100 has electrically grounded external walls 106, an internal wall 108, and a gas distribution assembly 110, which concurrently define a first chamber 102 and a second chamber 104. The first and second chambers 102 and 104 are isolated from one another by the internal wall 108. A pedestal 114 is disposed within each of the chambers 102 and 104, respectively. Each pedestal 114 is substantially centered with respective chamber centerlines 120A and 120B. The pedestal 114 is configured to support a substrate 116. The substrate 116 may rest, or alternately, be secured to the pedestal 114 through the use of electrostatic force, mechanical or vacuum clamping, gravitational force, and the like. A gas panel 112 is coupled to the CVD apparatus 100 and provides process and other gases as required for conventional CVD to occur within the first and second chambers 102 and 104. The CVD chamber 100 may also be coupled to an RF source 118.

In general, the CVD apparatus 100 may be known as the Producer® Reactor, which is commercially available from Applied Materials, Inc. of Santa Clara, Calif. The CVD apparatus 100 is described in detail in commonly assigned U.S. Ser. No. 09/609,994 (APPM 3402), filed Jul. 5, 2000 and entitled “APPARATUS FOR DISTRIBUTING GASES IN A CHEMICAL VAPOR DEPOSITION SYSTEM”, which is incorporated herein by reference. Although embodiments of the invention are described with reference to the Producer® Reactor, other CVD reactors and chambers may also be used to practice various embodiments of the invention, such as, the DXZ® Chamber, which is also commercially available from Applied Materials, Inc. of Santa Clara, Calif. The DXZ® Chamber is disclosed in commonly assigned U.S. Pat. No. 6,364,954 B2, issued Apr. 2, 2002, which is incorporated herein by reference.

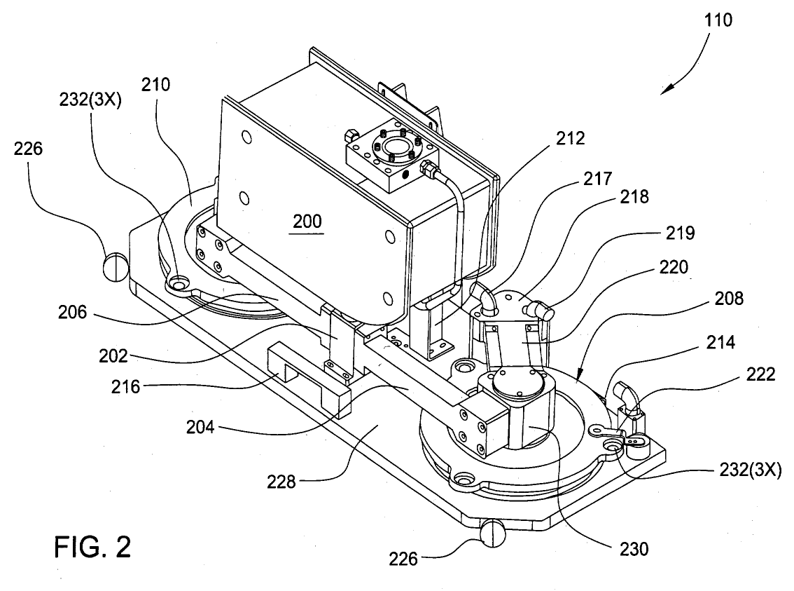

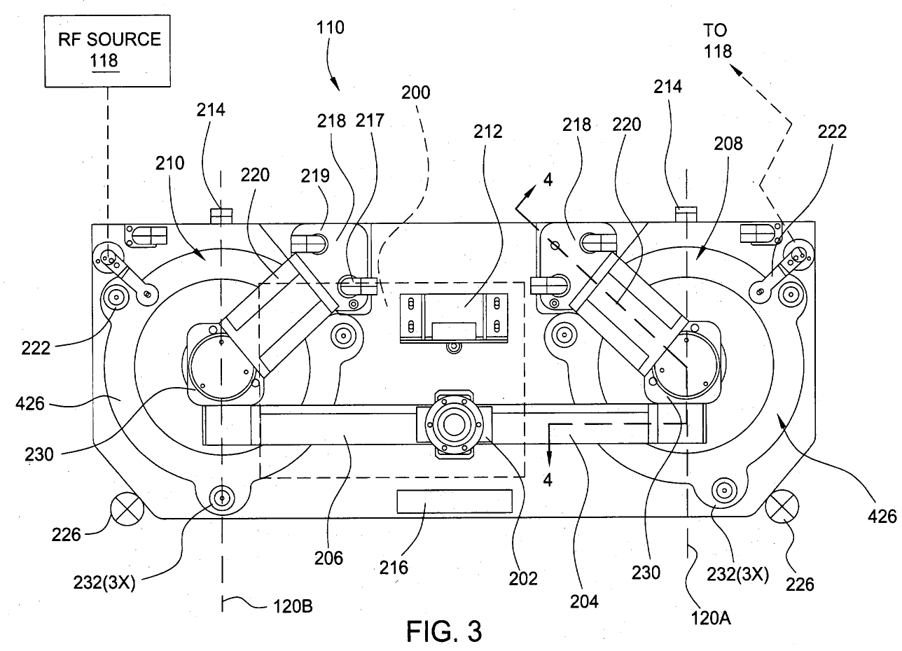

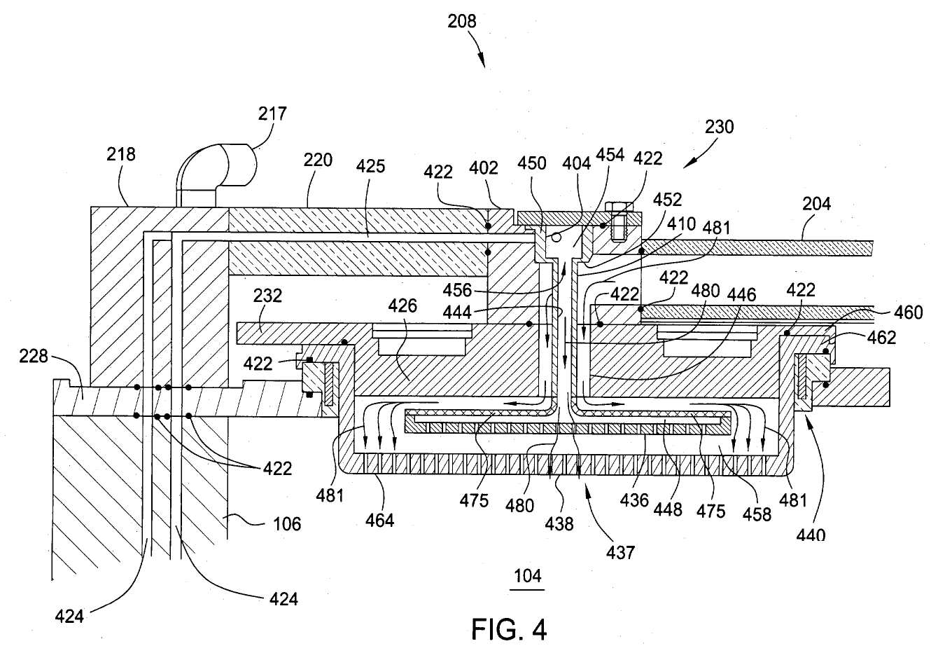

Referring now to FIGS. 2 and 3, perspective and top views of the gas distribution assembly 110 are illustrated. The gas distribution assembly 110 has a lid plate 228, a first gas box 208, a second gas box 210, and a remote plasma source 200. The lid plate 228 is generally fabricated from a conductive material, such as aluminum. The lid plate 228 is affixed to one of the exterior chamber walls 106 by one or more hinges 214. To facilitate the opening of the lid plate 228, a handle 216 is typically provided. A fastening mechanism 226, i.e., a captive latch, secures the lid plate 228 to the chambers 102 and 104 when the gas distribution assembly 110 in a closed position. The gas distribution assembly 110 additionally includes a pair of inlet manifolds 218 (one of which is partially obscured by the remote plasma source 200 in FIG. 2) and a pair of constant voltage gradient feed channels 220 (also, one of which is partially obscured by the remote plasma source 200 in FIG. 2). Each inlet manifold 218 is disposed upon the lid plate 228 adjacent to each gas box 208 and 210. The feed channel 220 defines a passage 425 (shown in FIG. 4) that connects each inlet manifold 218 to the respective gas box. The feed channel 220 is fully described in the commonly assigned U.S. Pat. No. 5,725,675, which is incorporated herein by reference. The feed channel 220 is configured to electrically isolate the inlet manifold 218 from the gas boxes 208 and 210. To control the temperature of the gas distribution assembly 110, each inlet manifold 218 includes an inlet heat exchange fitting and an outlet heat exchange fitting 217 and 219 respectively, for circulating a cooling fluid, e.g., water. The cooling fluid circulates at a temperature range of about 65 degrees Celsius to about 70 degrees Celsius through channels (not shown) extending through each inlet manifold 218 and the gas distribution assembly 110.

The remote plasma source 200 is configured to deliver and sustain a cleaning gas, such as, a halogen-containing gas, for removing unwanted deposition material from chambers 102 and 104. The remote plasma source 200 may be an ASTRON® generator, which is commercially available from MKS Instruments, Inc. of Wilmington, Mass. The remote plasma source 200 is centrally supported above the lid plate 228 by a bracket 212. The bracket 212 may be fastened to the lid plate 228 by conventional means such as welding, riveting, machine screws and the like.

The cleaning gas may be a halogen-containing gas, such as a fluorine-containing gas. Preferably, the cleaning gas is NF₃. The processing conditions and ranges described herein for cleaning gases can be used with NF₃. Other cleaning gases that can be used include F₂, C₄, C₃F₈, C₂F₄, SF₆, C₂F₆, CCl₄, and C₂Cl₆.

The remote plasma source 200 delivers the cleaning gas to the chambers 102 and 104 via a divider 202, a first conduit 204, and a second conduit 206. The divider 202 is coupled to the remote plasma source 200. The divider 202 is additionally coupled to both the first conduit 204 and the second conduit 206, forming a “tee”. The first conduit 204 couples the divider 202 to the first gas box 208 while the second conduit 206 couples the divider 202 to the second gas box 210. The first and second conduits 204 and 206 are fabricated from a dielectric material to electrically isolate the gas boxes 208 and 210 from the remote plasma source 200. The cleaning gas thus enters the respective chamber by flowing out of the remote plasma source 200 into the divider 202, then through the respective conduit and gas box into the respective chamber. Although the CVD apparatus 100 is described as having only a single remote plasma source 200, embodiments of the invention may be used with any chamber having any number of remote plasma sources. For example, a Producer® Reactor with two remote plasma sources is described in commonly assigned U.S. Ser. No. 10/122,481 filed Apr. 12, 2002 and entitled “METHOD FOR CLEANING A PROCESS CHAMBER,” which is incorporated herein by reference.

The first gas box 208 and second gas box 210 each include a mixing block 230, a mounting plate 426, an isolator 440, and a showerhead 437, as shown in FIG. 4. The showerhead 437 includes a blocker plate 436 and a gas distribution plate 438. The first gas box 208 is centrally disposed in the lid plate 228 along the chamber centerline 120A (shown in FIG. 3). The second gas box 210 is centrally disposed in the lid plate 228 along the chamber centerline 120B (shown in FIG. 3). The first and second gas boxes 208 and 210 are generally circular in shape, and have three mounting holes 232 in each mounting plate 426. The mounting plate 426 is fabricated from a conductive material, such as aluminum. An RF coupling tab 222 couples the mounting plate 426 of the first and second gas boxes 208 and 210 to the RF source 118. The RF power is coupled through the mounting plate 426 to the gas distribution plate 438.

The mixing block 230 is centrally disposed atop each of the gas boxes 208 and 210, respectively. The mixing block 230 includes a housing 402, a vortex generator 404, and a gas delivery tube 410. The vortex generator 404 has a wall 450 and a bottom 452 that define a substantially cylindrical interior volume 454. The bottom 452 has an exit aperture 456. The gas delivery tube 410, which has a center passage 444, is affixed to the bottom 452 of the vortex generator 404 and is defined through the mounting plate 426. The center passage 444 is generally aligned with the exit aperture 456 so that processing and other gases passing through the vortex generator 404 flow through the exit aperture 456 and center passage 444 and into the respective chamber. The vortex generator 404 is described in detail in commonly assigned U.S. Ser. No. 09/609,994 (APPM 3402), filed Jul. 5, 2000 and entitled “APPARATUS FOR DISTRIBUTING GASES IN A CHEMICAL VAPOR DEPOSITION SYSTEM”, which is incorporated herein by reference.

As illustrated in FIG. 4, the mixing block 230 is disposed upon the mounting plate 426. The mounting plate 426 has a flange 460 and is coupled to the RF coupling tab 222 (see FIG. 3). The mounting plate 426 has a center hole 446 to allow passage of the gas delivery tube 410 and the cleaning gas. Disposed below the mounting plate 426 is a shield 475, which is coupled to the gas delivery tube 410 at one end and to the blocker plate 436 at the other end. The shield 475 may be coupled to the gas delivery tube 410 and the blocker plate 436 by conventional means, such as welding and the like. The blocker plate 436 is perforated to allow gas passage. The blocker plate 436 and the shield 475 form a gap 448 that causes processing gases exiting the mixing block 230 to diffuse radially outward.

The shield 475 is configured to provide two separate pathways for cleaning and processing gases. One pathway is configured to direct processing gases to flow through the blocker plate 436 and the gas distribution plate 438, as illustrated by arrows 480. The other pathway is configured to direct cleaning gases to flow around the shield 475 and the blocker plate 436, and through the gas distribution plate 438, as illustrated by arrows 481. By directing the cleaning gases to flow around the blocker plate 436, the amount of cleaning gases (i.e., in the form of free radicals) that flow through the gas distribution plate 438, particularly at or around its perimeter, is increased. As the amount of cleaning gases that flow through the perimeter portion of the gas distribution plate 438 increases, the clean rate at the perimeter portion of the gas distribution plate 438 also increases. In this manner, the clean rate in the chamber, particularly at or around the perimeter of the gas distribution plate 438, is improved. In one embodiment, the pathway for the processing gases is defined by the internal portion of the shield 475. In another embodiment, the pathway for the cleaning gases is defined by the external portion of the shield 475, the mounting plate 426 and the gas distribution plate 438. The shield 475 may be fabricated from a conductive material, such as aluminum.

The gas distribution plate 438 is generally dish-shaped and defines a rim 462 and a perforated bottom 464. The gas distribution plate 438 may be fabricated from a conductive material, such as aluminum. The rim 462 of the gas distribution plate 438 abuts against the flange 460 and the isolator 440. The isolator 440 is configured to electrically insulate the respective gas box from the lid plate 228. The isolator 440 may be fabricated from an insulative dielectric material such as a fluoropolymer or ceramic.

Defined between the blocker plate 436 and the gas distribution plate 438 is a plenum 458. Processing gases that pass through the blocker plate 436 enter the plenum 458 and are subjected to a slight flow restriction caused by the perforated bottom 464 of the gas distribution plate 438. This causes the various gases to further diffuse radially across the gas distribution plate 438, causing a uniformly distributed flow of gas passing through the perforated bottom 464 and into the respective chamber.

A series of o-rings 422 are disposed between the isolator 440 and the lid plate 228, the isolator 440 and the gas distribution plate 438, the mixing block 230 and the mounting plate 426, and the gas distribution plate 438 and the feed channel 436 to ensure gas delivery into the respective chamber. The o-rings 422 are generally made of a material compatible with the processing and cleaning gases used in the CVD apparatus 100.

In operation, the wafer 116 is set upon the pedestal 114 in each of the chambers 102 and 104. A pump (not shown) evacuates the chambers 102 and 104. The processing gases are delivered to the mixing block 230 of each gas box 208 and 210, and thoroughly mixed in a cyclonic manner. Once mixed, the processing gases exit the mixing block 230 via the gas delivery tube 410, entering the respective chambers through the blocker plate 436 and the gas distribution plate 438. The processing gases then deposit a layer of material upon the wafer 116. In one embodiment, the layer of material may have a low dielectric constant, e.g. about 3 or less. Once the desired thickness of deposition is achieved, the processing gases are removed from the chambers 102 and 104.

Optionally, the deposition process may be enhanced by forming a plasma of the processing gases within the chamber. If desired, the optional RF power source 118 is coupled to the respective gas boxes via the RF coupling tab 222. The RF power may be coupled to the gas distribution plate 438 to bias the gas distribution plate 438, thereby igniting and sustaining the plasma of the mixed processing gases within the respective chamber.

After the wafers 116 have been removed, the respective chambers may be cleaned using the remote plasma source 200, which is configured to generate the cleaning gases (i.e., in the form of free radicals). Once generated, the cleaning gases are delivered through the divider 202 and the respective conduits to the respective gas boxes. From the respective gas boxes, the cleaning gases flow through the bore 418, which surrounds the gas delivery tube 410, around the shield 475 and the blocker plate 436, and through the gas distribution plate 438 in the manner described above. As the cleaning gases flow through various components in the respective chambers, those components, including the gas distribution plate 438, are effectively scrubbed or etched of substantially all material that may have been deposited during the deposition process.

Embodiments of the invention described herein are not limited to any specific apparatus or to any specific plasma excitation method. Although embodiments of the invention are described with reference to a remote plasma source, embodiments of the invention may also be practiced in connection with other clean operations, such as an in-situ clean operation. The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in substrate support pedestal design, heater design, gas box design, remote plasma source design, location of power connections and others are possible.

While the foregoing is directed to embodiments of the present invention, other and further embodiments of the invention may be devised without departing from the basic scope thereof, and the scope thereof is determined by the claims that follow.

What is claimed is:

1. An apparatus for distributing gases into a processing chamber, comprising:
a gas distribution plate defining a plurality of holes disposed therethrough;
a blocker plate defining a plurality of holes disposed therethrough;
a first gas pathway configured to deliver a first gas through the blocker plate and the gas distribution plate; and
a second gas pathway configured to deliver a second gas around the blocker plate and through the gas distribution plate.

2. The apparatus of claim 1, wherein the blocker plate is disposed above the gas distribution plate.

3. The apparatus of claim 1, wherein the first gas pathway is configured to deliver the first gas through the blocker plate prior to the gas distribution plate.

4. The apparatus of claim 1, wherein the second gas pathway is configured to deliver a substantial portion of the second gas through the plurality of holes disposed at a perimeter portion of the gas distribution plate.

5. The apparatus of claim 1, further comprising a shield configured to direct the second gas around the blocker plate.

6. The apparatus of claim 5, wherein the shield is disposed above the blocker plate.

7. The apparatus of claim 5, wherein the shield is coupled to an upper portion of the blocker plate.

8. The apparatus of claim 5, wherein an internal portion of the shield defines the first gas pathway.

9. The apparatus of claim 5, wherein the first gas pathway is defined inside the shield.

10. The apparatus of claim 5, wherein the second gas pathway is configured to direct the second gas to flow around an external portion of the shield and the blocker plate.

11. The apparatus of claim 5, further comprising a mounting plate on which the gas distribution plate is mounted, wherein an external portion of the shield and at least one of the mounting plate and the gas distribution plate define the second gas pathway.

12. The apparatus of claim 5, wherein the shield is configured to direct a substantial portion of the second gas to pass through the plurality of holes disposed at a perimeter portion of the gas distribution plate.

13. The apparatus of claim 5, wherein the shield is configured to direct the second gas around the blocker plate and to direct a substantial portion of the second gas through the plurality of holes disposed at a perimeter portion of the gas distribution plate.

14. The apparatus of claim 5, wherein the shield is configured to separate the first gas pathway from the second gas pathway.

15. The apparatus of claim 1, wherein the first gas is a processing gas.

16. The apparatus of claim 1, wherein the second gas is a cleaning gas.

17. The apparatus of claim 1, wherein first gas is a processing gas and the second gas is a cleaning gas.

18. The apparatus of claim 5, wherein the first gas is a processing gas.

19. The apparatus of claim 5, wherein the second gas is a cleaning gas.

20. The apparatus of claim 5, wherein first gas is a processing gas and the second gas is a cleaning gas.

21. The apparatus of claim 1, wherein the processing chamber is a chemical vapor deposition chamber.

22. A method for processing a substrate, comprising:
delivering one or more processing gases into a chemical vapor deposition chamber through a first gas pathway;
reacting the processing gases to deposit a material on a substrate surface;
removing the substrate from the chamber;
delivering one or more cleaning gases into the chamber through a second gas pathway, wherein the first gas pathway is separate from the second gas pathway; and
reacting the cleaning gases with deposits within the chamber until substantially all the deposits are consumed.

23. The method of claim 22, wherein delivering the processing gases through the first gas pathway comprises delivering the processing gases through a blocker plate and a gas distribution plate.

24. The method of claim 22, wherein delivering the cleaning gases through the second gas pathway comprises delivering the cleaning gases around the blocker plate and through the gas distribution plate.

25. The method of claim 22, wherein delivering the processing gases through the first gas pathway comprises delivering the processing gases through a blocker plate and a gas distribution plate; and wherein delivering the cleaning gases through the second gas pathway comprises delivering the cleaning gases around the blocker plate and through the gas distribution plate.

26. The method of claim 22, wherein delivering the cleaning gases comprises delivering the cleaning gases around the blocker plate such that a substantial portion of the cleaning gases pass through a perimeter portion of the gas distribution plate.

27. The method of claim 22, wherein the first gas pathway is separated from the second gas pathway by a shield.

28. The method of claim 27, wherein delivering the processing gases through the first gas pathway comprises delivering the processing gases through an internal portion of the shield.

29. The method of claim 27, wherein delivering the cleaning gases through the second gas pathway comprises delivering the processing gases around an external portion of the shield.

30. The method of claim 27, wherein delivering the cleaning gases through the second gas pathway comprises delivering the processing gases around an external portion of the shield and the blocker plate.
